(19) United States
(12) Patent Application Publication
(10) Pub. No.: US 2026/0093861 A1
(43) Pub. Date: Apr. 2, 2026

(54) MACHINE LEARNING-BASED ESTIMATION OF AIRCRAFT WEIGHT DISTRIBUTION

(71) Applicant: The Boeing Company, Arlington, VA (US)

(72) Inventors: Ravi Teja Peesapati, Bangalore (IN); Vinayak Suresh Kakamari, Bangalore (IN); Lakshmi Ethirajan, Bangalore (IN); Rumpa Kundu, Bangalore (IN)

(21) Appl. No.: 19/268,217

(22) Filed: Jul. 14, 2025

Related U.S. Application Data
(60) Provisional application No. 63/702,055, filed on Oct. 1, 2024.

(51) Int. Cl. G06F 30/15

(52) U.S. Cl. CPC G06F 30/15

(57) ABSTRACT

Examples are disclosed for estimating aircraft weight and center of gravity using a machine learning model. One example provides a computerized method, comprising receiving user input comprising data related to an aircraft, the data comprising an aircraft classification. The method further comprises obtaining parts data, determining an aircraft weight and a center of gravity for the aircraft based on the parts data, and outputting the aircraft weight and the center of gravity for the aircraft. Where parts data is omitted for one or more aircraft parts, a machine learning model comprising a clustering algorithm can be used to predict a weight and a location for the one or more aircraft parts. Examples are also disclosed for dynamically recomputing weight and center of gravity based on modifications to a digital model of the aircraft. The examples provide for secure storage of parts data without storing sensitive mission profile data.

### CROSS REFERENCE TO RELATED APPLICATIONS

This application claims priority to U.S. Provisional Patent Application Ser. No. 63/702,055, filed Oct. 1, 2024, the entirety of which is hereby incorporated herein by reference for all purposes.

### FIELD

The invention relates generally to computer methods of aircraft design, and more particularly, to automated methods of estimating weight and center of gravity of full aircraft based on stored parts data and estimations via machine learning models.

### BACKGROUND

Reliable weight and center of gravity estimations are crucial during the aircraft design process to help inform aerodynamics, control laws, landing gear design, etc. Typically, during aircraft design, weight and center of gravity are estimated manually by weight engineers in an iterative process, where weight estimations and center of gravity estimations are performed after each adjustment to the weight or the location of an individual aircraft part.

### SUMMARY

Example systems and methods for estimating an aircraft weight characteristic, such as an aircraft weight and center of gravity, using a machine learning (ML) model are disclosed. One example provides a computerized method for determining the weight of an aircraft. The method comprises receiving user input comprising data related to an aircraft, the data comprising an aircraft classification. The method further comprises inputting the data into a machine learning model comprising a clustering algorithm, the machine learning model configured to predict a weight and location for a plurality of aircraft parts. The method further comprises receiving, from the machine learning model, predicted parts data for one or more aircraft parts, the predicted parts data comprising a weight and location for each of the one or more aircraft parts. The method further comprises, based at least on the predicted parts data, determining a weight characteristic for the aircraft.

### BRIEF DESCRIPTION OF THE DRAWINGS

FIG. 1 schematically shows an example iterative aircraft design process that uses a modeling system for automated aircraft weight and center of gravity estimation.

FIG. 2 shows an example flow diagram for estimating aircraft weight using a ML model.

FIGS. 3A-3D schematically shows a clustering algorithm that can be used to predict weight and location of aircraft parts.

FIG. 4 shows a block diagram of an example computing system.

### DETAILED DESCRIPTION

As introduced above, weight estimation is an iterative process traditionally done manually by weight engineers. Weight estimations are used throughout the aircraft design process by different engineering teams. When an update to an aircraft part is proposed, engineers estimate updated values for the aircraft weight and center of gravity. As weight and center of gravity affect aerodynamics, control, and landing gear, changes to the aircraft design may prompt further updates from various engineering teams, such as aerodynamics, control law, and/or landing gear engineers. As such, due to it being done manually, the process of estimating weight and center of gravity (CG) of an aircraft is not only iterative but also can be error prone, time consuming, and labor and cost intensive. Further, the design of new aircraft can be challenging in instances where an aircraft part has not yet been built (i.e., it is not a preexisting part), and data thus does not exist for the part. Conventional weight estimation tools offer basic functionalities, but generally lack the abilities to do comprehensive analysis. Additionally, transfer and storage of weight data and mission profiles can pose security concerns, both for commercial and military applications.

Accordingly, examples are disclosed that relate to systems and methods for automating estimations of weight characteristics, such as weight and/or center of gravity, for an aircraft based on parts data. Estimations can be performed based on various operational conditions and mission profiles to form a digital twin (digital model) of an aircraft. Examples are further provided for estimating aircraft weight and center of gravity using machine learning (ML) models. Briefly, data related to an aircraft is input into an ML model. The data comprises information related to an aircraft classification, and optionally additional information related to weight and center of gravity for an aircraft fuselage, aircraft assemblies, and/or individual aircraft parts. Parts data missing from the input data can be predicted by the ML model, and the predicted values are used to form the digital model of the aircraft. As one example, the ML model can utilize a clustering algorithm to determine a predicted weight and center of gravity for each aircraft part based on stored data for the part (or similar parts) in prior aircraft designs. The examples further provide for automated estimations of moments of inertia based on predicted parts data for existing aircraft parts and new aircraft parts.

The disclosed examples also can allow for automated estimation of aircraft weight characteristics under various operational conditions and mission profiles. For example, the system can automatically estimate weight and CG of an empty aircraft, an aircraft with minimum fuel, and/or an aircraft with maximum fuel. The system can automatically estimate maximum “all-up” weight, maximum taxi weight, maximum landing weight, emergency landing weight, and normal landing weight. Further, the system can automatically estimate weight under various payload configurations. By automating estimation of aircraft weight and center of gravity, modifications of an aircraft design can be more easily validated.

The disclosed example systems and methods can perform automated weight estimations and weight predictions with minimal user input. Historical data for aircraft parts is collected and used to forecast parts data and aircraft weight for all mission profiles using a modeling system. For example, data can be grouped together as clusters. A densest cluster may provide the best estimation for weight and center of gravity. The detailed estimations can help weight engineers make informed decisions throughout the design process. Further, by reducing the iteration time for weight estimations, the modeling system can potentially save thousands of hours in labor costs for each new aircraft design, providing many direct and indirect benefits.

Additionally, the disclosed systems can provide a secure end-to-end solution for weight engineering. In some examples, weight data for a part is stored and/or transmitted without storing or transmitting mission profile data for the aircraft. As such, data for aircraft parts can be accessible by one or more remote computing systems, for example, without risking exposure of mission profile data. Storage of parts data can facilitate complex system integration and user access control. In this manner, the disclosed examples can help streamline and automate weight estimations with a curated catalog of parts data and secure storage/transfer of weight data.

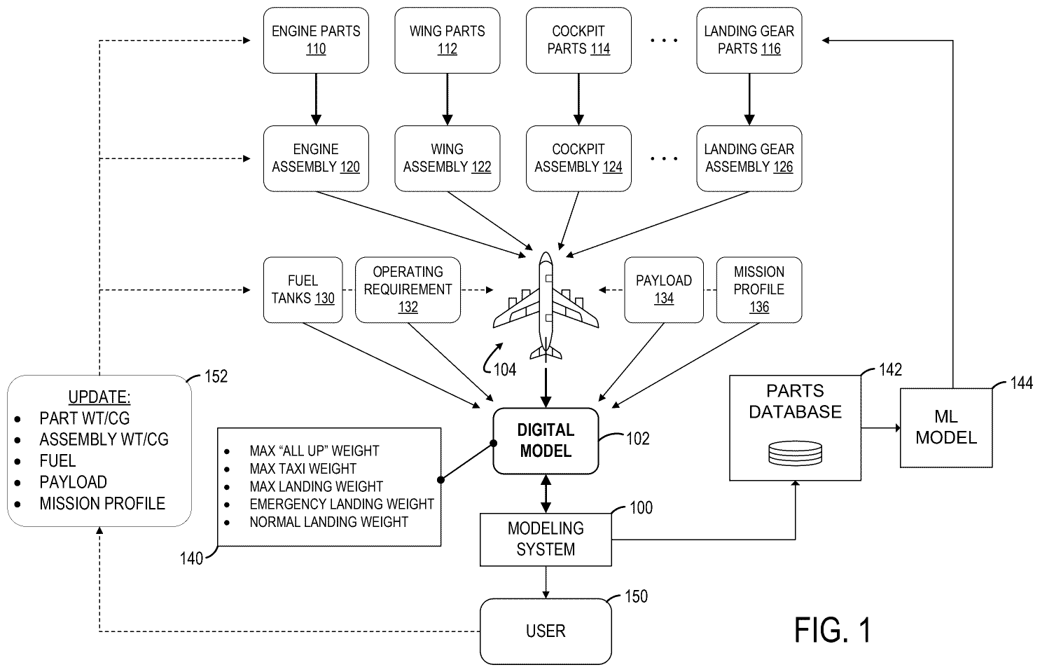

FIG. 1 schematically shows an example modeling system 100 that can be used to update aircraft parts data. The aircraft parts data is used by modeling system 100 to form a digital model 102 of an aircraft 104. Examples of aircraft include fixed-wing aircraft (e.g., airplanes), and rotary-wing aircraft (e.g., helicopters). More specific examples of aircraft include regional airplanes, narrow-body airplanes, wide-body airplanes, military airplanes, military helicopters, autonomous or semi-autonomous vehicles, and spacecraft.

Aircraft parts data comprises data for a plurality of aircraft parts. FIG. 1 shows examples of different types of aircraft parts, including engine parts 110, wing parts 112, cockpit parts 114, landing gear parts 116, and other parts not shown in FIG. 1. In some examples, an aircraft can have thousands-if not tens or hundreds of thousands—of aircraft parts. Parts data for an aircraft part can comprise any suitable data, such as a label (e.g., a part name or ID number), a weight, and/or a location. In the present disclosure, the location of an aircraft part refers to the location of a center of gravity (CG) of the aircraft part unless otherwise stated. Further examples of aircraft part data can include XYZ moments of inertia (Iₓ, I_{y}, I_{z}), a part level (e.g., engine part, wing part, etc.), and a year of manufacture. Aircraft parts data further can include information related to the size, shape, and/or structure of the aircraft part, such as CAD data.

Aircraft parts can form different assemblies, such as engine assembly 120, wing assembly 122, cockpit assembly 124, landing gear assembly 126, and other assemblies not shown in FIG. 1 (e.g., structures). As such, a part level for an aircraft part can indicate to which assembly the aircraft part belongs. As aircraft parts are joined together to form an assembly, the parts data for individual aircraft parts can be combined to determine aggregate data for the assembly. Assembly data can include any suitable data, such as parts data for each aircraft part, a location of each aircraft part within the assembly, an assembly weight, an assembly center of gravity, and XYZ moments of inertia for the assembly.

Continuing, the various aircraft assemblies are combined to form aircraft 104. Data for aircraft 104 can include parts data for each aircraft part, assembly data for each assembly, a location of each aircraft part/assembly, an aircraft weight, an aircraft center of gravity, and an aircraft moment of inertia.

To obtain a more complete aircraft model, additional information is considered, including fuel tanks data 130, aircraft operating requirement 132 (which includes crew and all fluids (e.g., engine oil, coolant, minimum fuel level, etc.) for basic operations), payload data 134, and mission profile data 136. Fuel tanks data 130 comprises data related to fuel tanks as well as fuel. For example, fuel tanks data 130 can comprise data related to weight and location of fuel tanks, fuel weight, and distribution of fuel throughout the fuel tanks at one or more fuel levels (sometimes referred to as fuel sequencing). The term “aircraft empty weight” can be used to refer to the weight of an aircraft with no fluids, crew, payload, or other contents. The term “aircraft operating empty weight” can be used to refer to the weight of an aircraft plus operating requirement. Payload data 134 can comprise a carrying capacity of the aircraft. Payload data 134 can comprise, for example, data related to cargo, people, and extra fuel. In some examples, such as for commercial aircraft, payload may refer to revenue-generating cargo/passengers exclusive of crew. Further, mission profile data 136 can comprise any suitable information related to a “mission” or flight plan. For example, mission profile data 136 can comprise information related to a flight distance, a starting fuel level, an ending fuel level, and an estimated fuel burn rate. In some examples, mission profile data 136 also can include information related to payload data 134.

Fuel tanks data 130, operating requirement 132, payload data 134, and mission profile data 136 is combined with data for aircraft 104 to form the digital model 102. As such, digital model 102 can comprise data related to aircraft parts, aircraft assemblies, fuel, operating requirement, payload, and mission profiles. Digital model 102 further can comprise data related to various conditional weights 140. As indicated at 140, the digital model comprises weight data related to a maximum “all-up” weight, a maximum taxi weight, a maximum landing weight, an emergency landing weight, and a normal landing weight. Further examples of conditional weights include a zero-fuel weight (a weight with no useable fuel, but loaded with passengers and cargo), and a regulated takeoff weight (which varies according to factors such as altitude, air temperature, length of runway, and others, but cannot exceed the maximum takeoff weight).

Digital model 102 is managed by modeling system 100. Modeling system 100 can be configured to determine an empty weight, and optionally one or more conditional weights 140 for the aircraft 104 based on the parts data and assembly data. For the empty weight and each conditional weight, the modeling system 100 also can determine a center of gravity and XYZ moments of inertia for the aircraft. In some examples, conditional weights can be similar despite the center of gravity being different. As an example, the center of gravity of an aircraft can shift—and moments of inertia can change—when landing gear is retracted.

Modifying the data that feeds into digital model 102 can cause the modeling system 100 to update digital model 102 and determine an updated aircraft weight and/or an updated conditional weight. Modeling system 100 can be configured to automatically update the digital model 102 upon receiving modification data related to one or more parts and/or one or more assemblies. Modeling system 100 further can be configured to automatically update digital model 102 based upon updates to fuel tanks data 130, operating requirement 132, payload data 134, and/or mission profile data 136. Upon updating digital model 102, modeling system 100 can automatically determine an updated weight and updated conditional weights. Modeling system 100 also can determine an updated center of gravity and updated XYZ moments of inertia for each weight and conditional weight.

Modeling system 100 is configured to store parts data within a parts database 142. As mentioned above, parts data can comprise any suitable data. Example data includes a name, an ID number, a weight, a location of a center of gravity, a moment of inertia, a part level, a year of manufacture, a size, a shape, and/or a structure of an aircraft part. In some examples, parts database 142 is stored on a computing system that is remote to a computing system implementing the modeling system 100. For example, modeling system 100 can output aircraft parts data to a cloud-based system for storage in parts database 142. In some examples, the modeling system 100 is configured to not output some types of data, such as fuel tanks data 130, operating requirement 132, payload data 134, and/or mission profile data 136 to parts database 142. As payload data and mission profile data can sometimes comprise sensitive information, by not storing mission profile data on parts database 142, the system can provide security against unauthorized access of parts database 142. Further, parts data stored in parts database 142 can be transferred without risk of exposing sensitive payload data or mission profile data.

Parts database 142 can function as a historical catalog for aircraft parts data. Parts database 142 can comprise data related to one or more types of aircraft in which a particular part is used. Parts database 142 can comprise data related to one or more specific models of aircraft in which a particular part is used. Parts database 142 also can comprise data related to parts manufacturing, cost, certification, and other information. Parts database 142 also can comprise data related to similar aircraft parts. For example, different versions of a lithium-ion battery may be considered as similar aircraft parts. As another example, parts having a same name or similar name may be considered as similar aircraft parts.

As mentioned above, ML methods can be used to help predict parts data missing from the digital model 102. For example, modeling system 100 can form a partial digital model based on user input, for example. Then, modeling system 100 can input data into a ML model 144. ML model 144 uses parts data from parts database 142 to predict parts data for one or more aircraft parts. In some examples, parts data is filtered by modeling system 100 based on an aircraft classification, for example, prior to inputting the parts data into the ML model 144. ML model 144 can be trained to predict a weight for the aircraft part based on weight data for the aircraft part and/or similar aircraft parts stored in parts database 142. Further, ML model 144 can be trained to predict a location of the center of gravity of an aircraft part based on a location of the aircraft part and/or similar aircraft parts stored in parts database 142. The predicted weight and center of gravity output by ML model 144 are used for the parts data for the aircraft part (e.g., engine parts 110, wing parts 112, cockpit parts 114, landing gear parts 116). The modeling system 100 can then automatically update parts data and assembly data in digital model 102, and automatically determine an updated weight, updated conditional weights, and corresponding centers of gravity.

The ML model 144 can use any suitable algorithm to predict parts data. In some examples, ML model 144 comprises a clustering algorithm. A clustering algorithm can be used to group data for an aircraft part into one or more clusters in multi-dimensional space. Clustering algorithms utilize a distance metric to determine similarity between elements. For example, a distance metric can be a cartesian distance between aircraft parts. A location of an aircraft part can be represented in XYZ coordinates from a reference point such as a center of gravity of the aircraft or center of gravity of an aircraft assembly. After clustering the data for an aircraft part, the ML model 144 can determine a predicted location of the aircraft part based on a centroid of a cluster. In some examples, the predicted location is based upon a centroid of a denser cluster of two or more clusters. In some examples, a distance metric can be further based on additional parts data, such as weight. For example, a clustering algorithm can perform clustering in four dimensions-XYZ coordinates and weight—and output predicted coordinates and weight based on a 4-dimensional centroid.

Any suitable clustering algorithm can be used for ML model 144. Examples include centroid-based clustering, density-based clustering, distribution-based clustering, and hierarchical clustering. More particular examples include k-means algorithms, balanced iterative reducing and clustering using hierarchies (BIRCH) algorithms, and density-based spatial clustering of applications with noise (DBSCAN) algorithms.

Additionally, modeling system 100 can output data (e.g., a weight and center of gravity) to a user 150, for example. In some examples, modeling system 100 can output data for display, e.g., using a graphical user interface. In the example depicted in FIG. 1, user 150 can represent one or more engineering teams, such as a control law team, an aerodynamics team, a structures team, or a landing gear team. User 150 can determine to make one or more updates to digital model 102, and supply modification data, as indicated at 152. For example, the user can update a part weight, a part center of gravity (CG), an assembly weight, an assembly center of gravity, fuel data, payload data, and/or mission profile data. Based on the modification data at 152, modeling system 100 can automatically update digital model 102 as described above. Modeling system 100 can perform updates to digital model 102 in real time based on user-supplied modification data 152. This can allow a user to quickly evaluate a proposed modification to the aircraft.

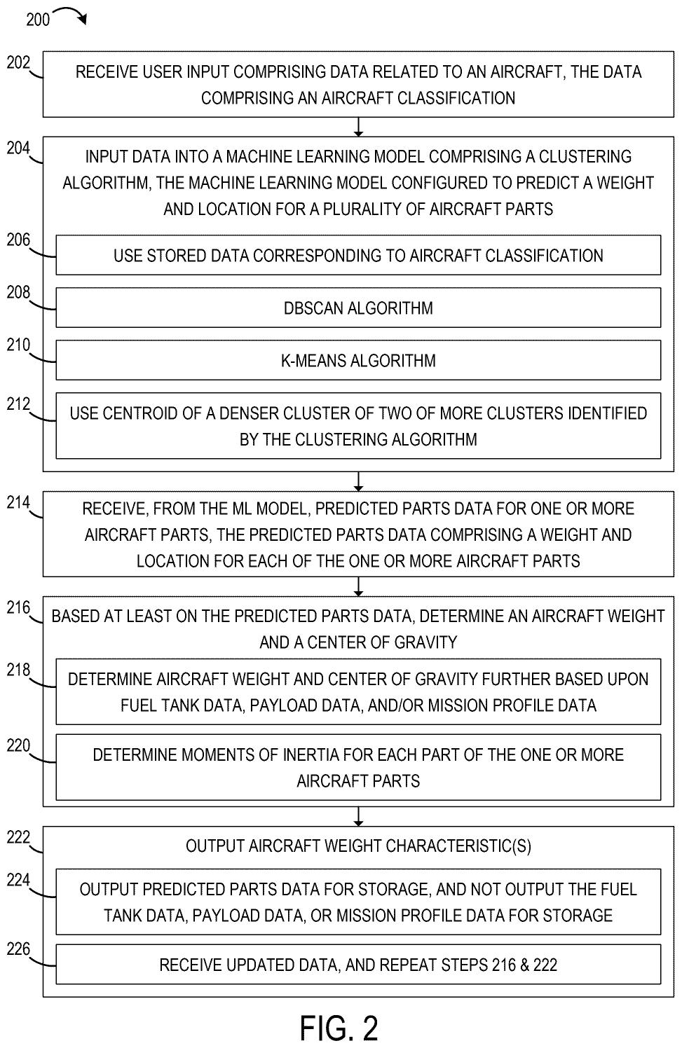

FIG. 2 shows a flow diagram for an example method 200 for estimating aircraft weight characteristic(s) using a ML model. Method 200 can be performed by a computing system implementing modeling system 100, for example. At 202, method 200 comprises receiving user input comprising data related to an aircraft, the data comprising an aircraft classification. Examples of aircraft include fixed-wing aircraft (e.g., airplanes), and rotary-wing aircraft (e.g., helicopters). More specific examples of aircraft include regional airplanes, narrow-body airplanes, wide-body airplanes, military airplanes, military helicopters, autonomous or semi-autonomous vehicles, and spacecraft.

In some examples, user input can comprise parts data for one or more aircraft parts of the aircraft. In some such examples, the user input can comprise parts data for each part of the aircraft. However, in examples where parts data is omitted for one or more aircraft parts (or all aircraft parts), a machine learning model can be used to predict weight and center of gravity for the missing aircraft parts.

Method 200 further comprises, at 204, inputting the data into a machine learning model (e.g., ML model 144) comprising a clustering algorithm, the machine learning model configured to predict a weight and location for a plurality of aircraft parts. In some examples, at 206, method 200 comprises using stored data corresponding to an aircraft classification. For example, a prediction of weight and center of gravity for a shock absorber of a regional jet can comprise inputting parts data for shock absorbers of regional jets into the ML model, and omitting parts data for other aircraft classifications. In some examples, at 208, the ML model comprises a DBSCAN algorithm. In some examples, at 210, the ML model comprises a k-means algorithm. In other examples, any other suitable algorithm can be used, such those discussed above. In some examples, at 212, method 200 comprises using a centroid of a denser cluster of two or more clusters identified by the clustering algorithm.

Continuing, method 200 further comprises, at 214, receiving, from the ML model, predicted parts data for one or more aircraft parts. The predicted parts data comprises a weight and location for each of the one or more aircraft parts. As mentioned above, in examples where the user input at 202 comprises parts data for all aircraft parts, steps 204 and 214 can be omitted.

Method 200 further comprises, at 216, based at least on the predicted parts data, determining an aircraft weight and center of gravity. In some examples, at 218, method 200 comprises determining the aircraft weight and center of gravity based on one or more of fuel tank data, payload data, and mission profile data. In some examples, step 216 comprises determining a plurality of conditional weights and corresponding plurality of centers of gravity. Examples of conditional weights include a maximum “all-up” weight, a maximum taxi weight, a maximum landing weight, an emergency landing weight, a normal landing weight, a zero-fuel weight, and a regulated takeoff weight. In some examples, at 220, method 200 further comprises determining moments of inertia for each part of the one or more aircraft parts. In some examples, method 200 also comprises determining moments of inertia for the aircraft.

Continuing, at 222, method 200 comprises outputting the aircraft weight characteristic(s), such as aircraft weight and center of gravity in some examples. Weight and center of gravity can be output to a user, for example. In some examples, the aircraft weight and center of gravity are output with a digital model to a user. In some examples, at 224, method 200 comprises outputting predicted parts data for storage, and not outputting the fuel tank data, payload data, or mission profile data for storage. In some examples, at 226, method 200 comprises receiving updated data, and repeating steps 216 and 222. Step 226 can comprise receiving updated data related to one or more aircraft parts, one or more assemblies, fuel tank data, payload data, and/or mission profile data.

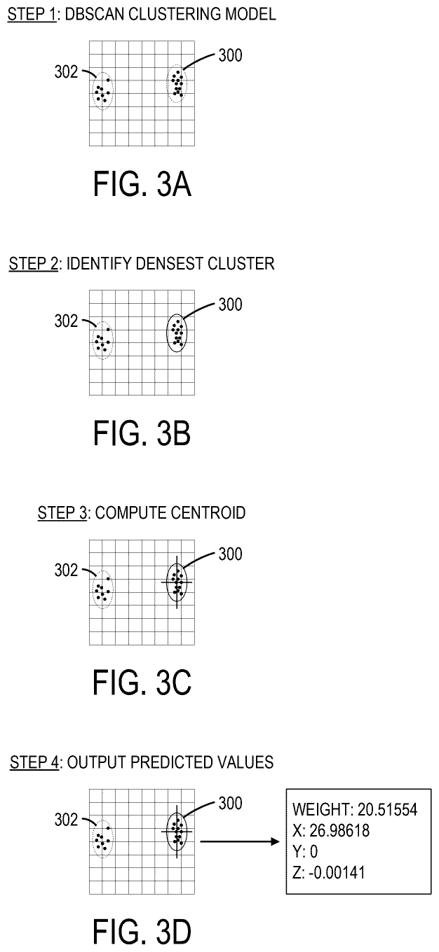

FIGS. 3A-3D schematically show an example unsupervised ML model that uses a clustering algorithm to predict a weight and center of gravity of an aircraft part. As discussed above, historical data is collected for aircraft parts. A weight and position (X, Y, and Z coordinate) is considered for calibration. Unsupervised ML methods are used, such as DBSCAN. FIG. 3A shows a first step of an example clustering algorithm in which a DBSCAN algorithm is used to cluster data for an aircraft part into cluster 300 and cluster 302. In this illustrative example, aircraft parts are in different locations across various aircraft. As such, cluster 300 is separated from cluster 302. In some examples, data may be clustered in a single cluster. In some examples, data may be clustered in two or more clusters. It is noted that DBSCAN does not utilize a number of clusters as a parameter. Rather, a number of clusters is inferred by the data. FIG. 3B shows a second step of the clustering algorithm where a densest cluster is identified. As shown in FIG. 3B, cluster 300 is identified as denser than cluster 302. In examples where data is clustered in a single cluster, the single cluster can be selected for predicting parts data.

Next, FIG. 3C shows a third step of the clustering algorithm where a centroid is computed for cluster 300. The densest cluster can be selected for the estimate of predicted parts data in some examples. Further, in some examples, more recent data can provide a best estimate. For example, a centroid for a cluster corresponding to more recent parts data (e.g., a year of manufacture within the past 5 years) can be selected over a centroid corresponding to older data. Finally, FIG. 3D shows a fourth step of the clustering algorithm where the location of the centroid is used to predict weight and XYZ coordinates for the location of the aircraft part. Predicted data can be output to be used in a digital model of an aircraft. For example, the predicted data for the aircraft part can be used by modeling system 100 to form digital model 102. In some examples, modeling system 100 can indicate to a user that predicted parts data is ML-generated data.

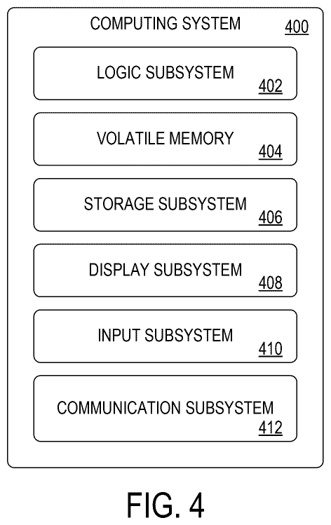

FIG. 4 shows a block diagram of an example computing system that can be utilized to implement the method 200 described above. Computing system 400 includes a logic subsystem 402, volatile memory 404, and a storage subsystem 406. Computing system 400 can optionally include a display subsystem 408, input subsystem 410, communication subsystem 412 connected to a computer network, and/or other components not shown in FIG. 4. These components are typically connected for data exchange by one or more data buses when integrated into single device, or by a combination of data buses, network data interfaces, and computer networks when integrated into separate devices connected by computer networks.

The storage subsystem 406 stores various instructions, also referred to as software, that are executed by the logic subsystem 402. Logic subsystem 402 includes one or more physical devices configured to execute the instructions. For example, the logic subsystem 402 can be configured to execute instructions that are part of one or more applications, programs, routines, libraries, objects, components, data structures, or other logical constructs. Such instructions can be implemented to perform a task, implement a data type, transform the state of one or more components, achieve a technical effect, or otherwise arrive at a desired result.

The logic subsystem 402 can include one or more physical processors (hardware) configured to execute software instructions. Additionally, or alternatively, the logic subsystem 402 can include one or more hardware logic circuits or firmware devices configured to execute hardware-implemented logic or firmware instructions. Processors of the logic subsystem 402 can be single-core or multi-core, and the instructions executed thereon can be configured for sequential, parallel, and/or distributed processing. Individual components of the logic subsystem 402 optionally can be distributed among two or more separate devices, which can be remotely located and/or configured for coordinated processing. Aspects of the logic subsystem 402 can be virtualized and executed by remotely accessible, networked computing devices configured in a cloud-computing configuration. In such a case, these virtualized aspects are run on different physical logic subsystems of various different machines, it will be understood.

Storage subsystem 406 includes one or more physical devices configured to hold instructions executable by the logic subsystems to implement the methods and processes described herein. When such methods and processes are implemented, the state of storage subsystem 406 can be transformed e.g., to hold different data.

Storage subsystem 406 can include physical devices that are removable and/or built-in. Storage subsystem 406 can include optical memory (e.g., CD, DVD, HD-DVD, Blu-Ray Disc, etc.), semiconductor memory (e.g., ROM, EPROM, EEPROM, FLASH memory, etc.), and/or magnetic memory (e.g., hard-disk drive, floppy-disk drive, tape drive, MRAM, etc.), or other mass storage device technology. Storage subsystem 406 can include nonvolatile, dynamic, static, read/write, read-only, sequential-access, location-addressable, file-addressable, and/or content-addressable devices. It will be appreciated that storage subsystem 406 is configured to hold instructions even when power is cut to the storage subsystem 406.

Volatile memory 404 can include physical devices that include random access memory. Volatile memory 404 is typically utilized by logic subsystem 402 to temporarily store information during processing of software instructions. It will be appreciated that volatile memory 404 typically does not continue to store instructions when power is cut to the volatile memory 404.

Aspects of logic subsystem 402, volatile memory 404, and storage subsystem 406 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

The terms “module,” “program,” and “engine” can be used to describe an aspect of the modeling system 100 typically implemented in software by a processor to perform a particular function using portions of volatile memory, which function involves transformative processing that specially configures the processor to perform the function. Thus, a module, program, or engine can be instantiated via logic subsystem 402 executing instructions held by storage subsystem 406, using portions of volatile memory 404. It will be understood that different modules, programs, and/or engines can be instantiated from the same application, service, code block, object, library, routine, API, function, etc. Likewise, the same module, program, and/or engine can be instantiated by different applications, services, code blocks, objects, routines, APIs, functions, etc. The terms “module,” “program,” and “engine” can encompass individual or groups of executable files, data files, libraries, drivers, scripts, database records, etc.

Display subsystem 408 typically includes one or more displays, which can be physically integrated with or remote from a device that houses the logic subsystem 402. Graphical output of the logic subsystem executing the instructions described above, such as a graphical user interface, is configured to be displayed on display subsystem 408.

Input subsystem 410 typically includes one or more of a keyboard, pointing device (e.g., mouse, trackpad, finger operated pointer), touchscreen, microphone, and camera (e.g., camera 110). Other input devices can also be provided.

Communication subsystem 412 is configured to communicatively couple various computing devices described herein with each other, and with other devices. Communication subsystem 412 can include wired and/or wireless communication devices compatible with one or more different communication protocols. As non-limiting examples, the communication subsystem can be configured for communication via a wireless telephone network, or a wired or wireless local- or wide-area network by devices such as a 3G, 4G, 5G, or 6G radio, WIFI card, ethernet network interface card, BLUETOOTH radio, etc. In some embodiments, the communication subsystem can allow computing system 400 to send and/or receive messages to and/or from other devices via a network such as the Internet. It will be appreciated that one or more of the computer networks via which communication subsystem 412 is configured to communicate can include security measures such as user identification and authentication, access control, malware detection, enforced encryption, content filtering, etc., and can be coupled to a wide area network (WAN) such as the Internet.

The subject disclosure includes all novel and non-obvious combinations and subcombinations of the various features and techniques disclosed herein. The various features and techniques disclosed herein are not necessarily required of all examples of the subject disclosure. Furthermore, the various features and techniques disclosed herein can define patentable subject matter apart from the disclosed examples and can find utility in other implementations not expressly disclosed herein.

To the extent that terms “includes,” “including,” “has,” “contains,” and variants thereof are used herein, such terms are intended to be inclusive in a manner similar to the term “comprises” as an open transition word without precluding any additional or other elements.

Further, the disclosure comprises configurations according to the following examples.

Example 1. A computerized method for determining an aircraft weight and a center of gravity of an aircraft, the method comprising receiving user input data comprising data related to the aircraft, the data comprising an aircraft classification; inputting the user input data into a machine learning model configured to predict at least a weight and location for at least one part of a plurality of aircraft parts of the aircraft; receiving, from the machine learning model, predicted parts data for the at least one part, the predicted parts data comprising at least the weight and the location for the at least one part; and based at least on the predicted parts data, determining the aircraft weight and the center of gravity for the aircraft.

Example 2. The computerized method of example 1, wherein the machine learning model comprises a clustering algorithm.

Example 3. The computerized method of example 2, wherein the clustering algorithm comprises one or more of a density-based spatial clustering of applications with noise (DBSCAN) algorithm or a k-means algorithm.

Example 4. The computerized method of example 1, wherein the machine learning model is configured to predict the weight and the location for the at least one part based at least on stored data comprising parts data corresponding to the aircraft classification.

Example 5. The computerized method of example 2, wherein the machine learning model is configured to predict the weight and the location of the at least one part by using a centroid of a denser cluster of two or more clusters identified by the clustering algorithm.

Example 6. The computerized method of example 1, further comprising receiving one or more of fuel tank data, payload data, or mission profile data, and wherein the determining the aircraft weight and the center of gravity is further based upon the one or more of the fuel tank data, the payload data, or the mission profile data.

Example 7. The computerized method of example 6, further comprising outputting the predicted parts data for storage in a database.

Example 8. The computerized method of example 1, further comprising receiving modified data for a part of the one or more aircraft parts, and repeating the determining the aircraft weight and the center of gravity.

Example 9. The computerized method of example 1, further comprising, based at least on the predicted parts data, determining a moment of inertia for the at least one part.

Example 10. A computing device, comprising a logic subsystem; and a storage subsystem implementing an aircraft parts database, the storage system further implementing a machine learning model, the machine learning model configured to predict a weight and a location for at least one part based at least on parts data stored in the aircraft parts database, the storage system further comprising instructions executable by the logic subsystem to: receive user input comprising data related to an aircraft, the data comprising a classification, an aircraft weight, and a center of gravity for an aircraft, input the data into the machine learning model, receive, from the machine learning model, predicted parts data for the at least one part, the predicted parts data comprising the weight and the location for the at least one part, and based at least on the predicted parts data, determining the aircraft weight and the center of gravity for the aircraft.

Example 11. The computing device of example 10, wherein the instructions are further executable to receive mission profile data, and to determine the aircraft weight and the center of gravity of the aircraft further based upon the mission profile data.

Example 12. The computing device of example 11, wherein the instructions are further executable to store the predicted parts data in the parts database, and not store the mission profile data.

Example 13. The computing device of example 10, wherein the machine learning model comprises one or more of a density-based spatial clustering of applications with noise (DBSCAN) algorithm or a k-means algorithm.

Example 14. The computing device of example 10, wherein the machine learning model is configured to predict the weight and the location for the at least one part based on parts data corresponding to the classification of the aircraft.

Example 15. The computing device of example 10, wherein the instructions are further executable to determine XYZ moments of inertia for the at least one part.

Example 16. A computerized method for determining the weight and center of gravity of an aircraft, the method comprising obtaining a computer model of an aircraft, the computer model comprising, for at least one part of a plurality of aircraft parts of the aircraft, a weight, XYZ coordinates of a center of gravity, and XYZ moments of inertia; receiving modification data related to one or more modifications to the aircraft; and based on the modification data, updating the computer model of the aircraft to form an updated computer mode.

Example 17. The computerized method of example 16, wherein the modification data comprises an update to one or more of an aircraft part weight, an aircraft part location, an aircraft assembly weight, an aircraft assembly location, an aircraft fuel tank weight, an aircraft fuel tank location, an aircraft payload, or an aircraft mission profile.

Example 18. The computerized method of example 16, wherein the obtaining the computer model of the aircraft comprises inputting parts data into a trained machine learning model comprising a clustering algorithm to obtain a predicted weight and predicted XYZ coordinates for one or more aircraft parts of the plurality of aircraft parts.

Example 19. The computerized method of example 16, further comprising updating the computer model in real time.

Example 20. The computerized method of example 16, further comprising storing parts data for the plurality of aircraft parts for the updated computer model in a database.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A computerized method for determining a weight characteristic of an aircraft, the method comprising:
receiving user input data comprising data related to the aircraft, the data comprising an aircraft classification;
inputting the user input data into a machine learning model configured to predict at least a weight and location for at least one part of a plurality of aircraft parts of the aircraft;
receiving, from the machine learning model, predicted parts data for the at least one part, the predicted parts data comprising at least the weight and the location for the at least one part; and
based at least on the predicted parts data, determining the weight characteristic for the aircraft.

2. The computerized method of claim 1, wherein the machine learning model comprises a clustering algorithm comprising one or more of a density-based spatial clustering of applications with noise (DBSCAN) algorithm or a k-means algorithm.

3. The computerized method of claim 1, wherein the weight characteristic comprises one or more of an aircraft weight or a center of gravity.

4. The computerized method of claim 1, wherein the machine learning model is configured to predict the weight and the location for the at least one part based at least on stored data comprising parts data corresponding to the aircraft classification.

5. The computerized method of claim 2, wherein the machine learning model is configured to predict the weight and the location of the at least one part by using a centroid of a denser cluster of two or more clusters identified by the clustering algorithm.

6. The computerized method of claim 1, further comprising receiving one or more of fuel tank data, payload data, or mission profile data, and wherein the determining the aircraft weight and the center of gravity is further based upon the one or more of the fuel tank data, the payload data, or the mission profile data.

7. The computerized method of claim 6, further comprising outputting the predicted parts data for storage in a database.

8. The computerized method of claim 1, further comprising receiving modified data for a part of the one or more aircraft parts, and repeating the determining the aircraft weight and the center of gravity.

9. The computerized method of claim 1, further comprising, based at least on the predicted parts data, determining a moment of inertia for the at least one part.

10. A computing device, comprising:
a logic subsystem; and
a storage subsystem implementing an aircraft parts database, the storage system further implementing a machine learning model, the machine learning model configured to predict a weight and a location for at least one part based at least on parts data stored in the aircraft parts database, the storage system further comprising instructions executable by the logic subsystem to:
receive user input comprising data related to an aircraft, the data comprising a classification, an aircraft weight, and a center of gravity for an aircraft,
input the data into the machine learning model,
receive, from the machine learning model, predicted parts data for the at least one part, the predicted parts data comprising the weight and the location for the at least one part, and
based at least on the predicted parts data, determining the aircraft weight and the center of gravity for the aircraft.

11. The computing device of claim 10, wherein the instructions are further executable to receive mission profile data, and to determine the aircraft weight and the center of gravity of the aircraft further based upon the mission profile data.

12. The computing device of claim 11, wherein the instructions are further executable to store the predicted parts data in the parts database, and not store the mission profile data.

13. The computing device of claim 10, wherein the machine learning model comprises one or more of a density-based spatial clustering of applications with noise (DBSCAN) algorithm or a k-means algorithm.

14. The computing device of claim 10, wherein the machine learning model is configured to predict the weight and the location for the at least one part based on parts data corresponding to the classification of the aircraft.

15. The computing device of claim 10, wherein the instructions are further executable to determine XYZ moments of inertia for the at least one part.

16. A computerized method for determining a weight characteristic of an aircraft, the method comprising:
obtaining a computer model of an aircraft, the computer model comprising, for at least one part of a plurality of aircraft parts of the aircraft,
a weight,
XYZ coordinates of a center of gravity, and
XYZ moments of inertia;
receiving modification data related to one or more modifications to the aircraft; and
based on the modification data, updating the computer model of the aircraft to form an updated computer mode.

17. The computerized method of claim 16, wherein the modification data comprises an update to one or more of an aircraft part weight, an aircraft part location, an aircraft assembly weight, an aircraft assembly location, an aircraft fuel tank weight, an aircraft fuel tank location, an aircraft payload, or an aircraft mission profile.

18. The computerized method of claim 16, wherein the obtaining the computer model of the aircraft comprises inputting parts data into a trained machine learning model comprising a clustering algorithm to obtain a predicted weight and predicted XYZ coordinates for one or more aircraft parts of the plurality of aircraft parts.

19. The computerized method of claim 16, further comprising updating the computer model in real time.

20. The computerized method of claim 16, wherein the weight characteristic comprises one or more of a weight or a center of gravity of the aircraft.
